(19) United States
(12) Patent Application Publication
(10) Pub. No.: US 2010/0231543 A1
(43) Pub. Date: Sep. 16, 2010

(54) DISPLAY DEVICE WITH TOUCH SENSOR FUNCTION, MANUFACTURING METHOD OF DISPLAY DEVICE WITH TOUCH SENSOR FUNCTION, AND ELECTRONIC APPARATUS

(75) Inventor: Seigo Momose, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/717,311

(22) Filed: Mar. 4, 2010

(30) Foreign Application Priority Data
Mar. 13, 2009 (JP) 2009-062098

(51) Int. Cl. G06F 3/041; H05K 3/00

(52) U.S. Cl. 345/173; 427/96.1

(57) ABSTRACT

A display device with a touch sensor function includes: a first substrate; a second substrate which is disposed opposite the first substrate and has a touch surface at an opposite side of the first substrate; a display unit provided between the first and second substrates; display electrodes which are provided on both a surface of the first substrate facing the display unit and a surface of the second substrate facing the display unit and which control display of the display unit; and touch electrodes for detecting the touch position on the touch surface which are provided on both the surface of the first substrate facing the display unit and the surface of the second substrate facing the display unit and which come in contact with each other by a touch operation on the touch surface, the touch electrodes provided on at least one of both the surfaces being provided to protrude toward the display unit side, wherein each of the touch electrodes provided on the one surface has a contact surface, which is a curved surface with a convex shape, and is formed of an elastic material.

### BACKGROUND

1. Technical Field

The present invention relates to a display device with a touch sensor function, a manufacturing method of a display device with a touch sensor function, and an electronic apparatus.

2. Related Art

In recent years, touch panel devices have come into wide use as input devices for operating electronic apparatuses, such as an automatic teller machine (ATM). Such touch panel devices are mounted on the display surface sides of various display devices, such as liquid crystal display devices, and perform various kinds of operation, input, and the like of electronic apparatuses by specifying the contact position when the arbitrary position on a touch surface is touched by an input device such as a touch pen, a finger of a human being, or the like according to the display contents of the display devices viewed through the touch panel devices. Various types of devices, such as a resistive film type device, a capacitance coupling type device, and a surface acoustic wave type device, are known as the touch panel devices.

JP-A-2001-75074 discloses a touch sensor type liquid crystal display device in which a touch sensor and a liquid crystal display device are integrally formed. Such a touch sensor type liquid crystal display device includes first and second substrates provided opposite each other, a liquid crystal layer interposed between the substrates, and a touch electrode for detection of the touch position and a display electrode which are provided on at least one side of a liquid crystal layer side of the first substrate and a liquid crystal layer side of the second substrate.

Such a touch sensor type liquid crystal display device can be made thin and is excellent in optical transparency, compared with a case where a touch sensor and a liquid crystal display device are separately provided.

In such a touch sensor type liquid crystal display device, however, it is not possible to detect the strength of touch even though the touch position can be detected on the basis of whether or not a current flows through the touch electrode. For this reason, in the touch sensor type liquid crystal display device, for example, even if the touch surface is traced to draw a character, a line is only drawn along the traced locus. Accordingly, it was not possible to reproduce the writing pressure or to reproduce the information corresponding to the individual handwriting.

### SUMMARY

An advantage of some aspects of the invention is that it provides a display device with a touch sensor function which is thin and has high optical transparency and which allows a different input operation corresponding to the strength of touch to be performed on the display device since the information other than the touch position can also be detected by changing the strength of touch on a touch surface, a manufacturing method of the display device with a touch sensor function, and an electronic apparatus including the display device with a touch sensor function.

According to an aspect of the invention, there is provided a display device with a touch sensor function including: a first substrate; a second substrate which is disposed opposite the first substrate and has a touch surface at an opposite side of the first substrate; a display unit provided between the first and second substrates; display electrodes which are provided on both a surface of the first substrate facing the display unit and a surface of the second substrate facing the display unit and which control display of the display unit; and touch electrodes for detecting the touch position on the touch surface which are provided on both the surface of the first substrate facing the display unit and the surface of the second substrate facing the display unit and which come in contact with each other by a touch operation on the touch surface, the touch electrodes provided on at least one of both the surfaces being provided to protrude toward the display unit side. Each of the touch electrodes provided on the one surface has a contact surface, which is a curved surface with a convex shape, and is formed of an elastic material.

In this case, it is possible to obtain a display device with a touch sensor function which is thin and has high optical transparency and which allows a different input operation corresponding to the strength of touch to be performed on the display device since the information other than the touch position can also be detected by changing the strength of touch on a touch surface.

In the display device with a touch sensor function according to the aspect of the invention, it is preferable that each of the touch electrodes provided on the one surface is formed as an approximately spherical body.

In this case, when arraying the spherical bodies by discharging the spherical bodies from an ink jet head, the spherical bodies are not easily caught in nozzles of the ink jet head. Accordingly, the spherical bodies can be arrayed with high precision.

In the display device with a touch sensor function according to the aspect of the invention, it is preferable that each of the touch electrodes provided on the one surface is formed as a columnar body with a curved convex portion on a front end.

In this case, the touch electrodes provided on the one surface can be fixed to the first substrate more reliably. In the display device with a touch sensor function according to the aspect of the invention, it is preferable that each of the touch electrodes provided on the one surface has a core portion, which is formed of an elastic material, and a conductive layer which covers the core portion.

Accordingly, as the elastic material, a material which is optimal from a point of view of elasticity may be used regardless of conductivity.

In the display device with a touch sensor function according to the aspect of the invention, it is preferable that the elastic material is a styrene based thermoplastic elastomer.

In this case, even if the touch electrodes provided on the one surface deform repeatedly through touch operations, it is difficult for the elasticity to be adversely affected, and it is possible to maintain the elasticity over a long period of time.

In the display device with a touch sensor function according to the aspect of the invention, it is preferable that the elastic material is an elastic resin material containing conductive fillers therein.

In this case, since the conductive fillers are brought closer to each other when the touch electrodes provided on the one surface deform in the flat shape through a touch operation, the conductivity of the touch electrode itself provided on the one surface is improved. As a result, since not only the contact resistance is reduced but also the conductivity is improved by the touch operation, a change in the pressing force can be detected with high precision.

In the display device with a touch sensor function according to the aspect of the invention, it is preferable that a protrusion height of each of the touch electrodes provided on the one surface is 50 to 95% of the thickness of the display unit in a state where no touch operation has been performed on the touch surface.

In this case, an improvement in detection sensitivity of the touch electrodes and a suppression of erroneous detection become highly compatible.

In the display device with a touch sensor function according to the aspect of the invention, it is preferable that a touch position on the touch surface and the strength of a touch operation are detected according to the contact area between the touch electrodes provided on the one surface and the other electrodes provided on the other surface.

In this case, for example, when writing a character by tracing the touch surface with a finger, not only the information on the locus traced by the finger but also the information corresponding to so-called writing pressure can be acquired. Accordingly, by adding the information on the writing pressure to the information on the locus, it is possible to generate the input data in which individually different handwriting is sufficiently reproduced.

In the display device with a touch sensor function according to the aspect of the invention, it is preferable that the touch electrodes are provided corresponding to pixels of the display unit.

In this case, the positional accuracy in detection of the touch position can be improved.

In the display device with a touch sensor function according to the aspect of the invention, it is preferable to further include spacers which are provided for every pixel of the display unit so as to be adjacent to the touch electrodes and which regulate a distance between the first and second substrates.

In this case, the distance between the first and second substrates can be accurately controlled. In addition, even if a touch operation is repeatedly performed over a long period of time, a problem is suppressed in which the second substrate which once bent does not return to the original shape. As a result, it is possible to obtain a display device which can show a touch sensor function which is excellent over along period of time.

In the display device with a touch sensor function according to the aspect of the invention, it is preferable that the display unit is a liquid crystal layer.

In this case, it is possible to obtain a liquid crystal display device with a touch sensor function which is thin and has high optical transparency and which allows a different input operation corresponding to the strength of touch to be performed on the display device since the information other than the touch position can also be detected by changing the strength of touch on a touch surface.

According to another aspect of the invention, a manufacturing method of a display device with a touch sensor function including a first substrate, a second substrate which is disposed opposite the first substrate and has a touch surface at an opposite side of the first substrate, a display unit provided between the first and second substrates, display electrodes which are provided on both a surface of the first substrate facing the display unit and a surface of the second substrate facing the display unit and which control display of the display unit, and touch electrodes for detecting the touch position on the touch surface which are provided on both the surface of the first substrate facing the display unit and the surface of the second substrate facing the display unit, the touch electrodes provided on at least one of both the surfaces being provided to protrude toward the display unit side, includes: disposing the touch electrodes provided on the one surface by ejecting from ink nozzles for an ink jet head.

In this case, since the touch electrodes provided on the one surface can be arrayed simply and accurately, a display device with a touch sensor function excellent in detection accuracy of the touch position and the pressing force of a touch operation can be manufactured efficiently.

In the manufacturing method of a display device with a touch sensor function according to the aspect of the invention, it is preferable that the touch electrodes provided on the one surface are provided corresponding to pixels of the display unit and a nozzle pitch between the ink nozzles for the ink jet head is equivalent to a pixel pitch of the display unit.

In this case, the arrangement accuracy of the touch electrodes provided on the one surface can be further improved.

According to still another aspect of the invention, there is provided an electronic apparatus including the display device with a touch sensor function described above.

In this case, it is possible to obtain a high-performance electronic apparatus including a display device with a touch sensor function which allows a different input operation corresponding to the strength of touch to be performed on the display device since the information other than the touch position can also be detected by changing the strength of touch on a touch surface.

### BRIEF DESCRIPTION OF THE DRAWINGS

The invention will be described with reference to the accompanying drawings, wherein like numbers reference like elements.

FIG. 1 is a cross-sectional view showing a display device with a touch sensor function according to a first embodiment of the invention.

FIG. 2 is a plan view showing a TFT array substrate provided in the display device with a touch sensor function shown in FIG. 1.

FIGS. 3A to 3C are views illustrating an operation of the display device with a touch sensor function shown in FIG. 1.

FIG. 4 is a circuit diagram schematically illustrating a touch position detecting method in a touch sensor function.

FIG. 5A is a partially enlarged view showing the neighborhood of a touch electrode shown in FIG. 3B.

FIG. 5B is a partially enlarged view showing the neighborhood of a touch electrode shown in FIG. 3C.

FIG. 6 is a view illustrating a manufacturing method of the display device with a touch sensor function of the invention.

FIG. 7 is a cross-sectional view showing a display device with a touch sensor function according to a second embodiment of the invention.

FIG. 8 is a cross-sectional view showing a display device with a touch sensor function according to a third embodiment of the invention.

FIG. 9 is a perspective view showing the configuration of a mobile phone (PHS is also included) to which an electronic apparatus of the invention has been applied.

### DESCRIPTION OF EXEMPLARY EMBODIMENTS

Hereinafter, a display device with a touch sensor function, a manufacturing method of a display device with a touch sensor function, and an electronic apparatus according to preferred embodiments of the invention will be described with reference to the accompanying drawings.

### Display Device with a Touch Sensor Function

### First Embodiment

First, a display device with a touch sensor function according to a first embodiment of the invention will be described.

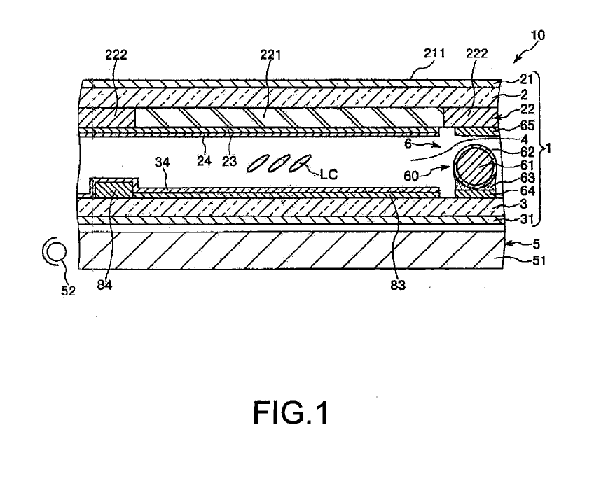

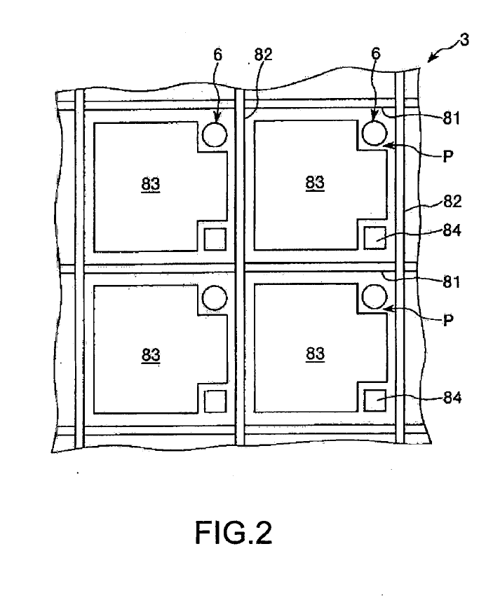

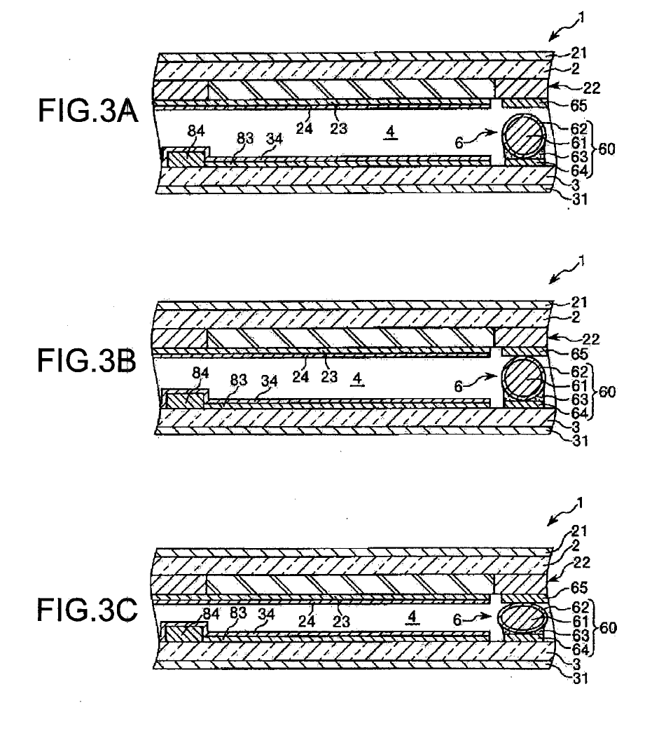

FIG. 1 is a cross-sectional view showing a display device with a touch sensor function according to the first embodiment of the invention, FIG. 2 is a plan view of a TFT array substrate provided in the display device with a touch sensor function shown in FIG. 1, and FIGS. 3A to 3C are views for explaining an operation of the display device with a touch sensor function shown in FIG. 1. In addition, in the following explanation, it is assumed that upper sides in FIGS. 1 and 3A to 3C are “upper” and lower sides are “lower”. In addition, one of a number of pixels provided in the display device with a touch sensor function is representatively shown in FIGS. 1 and 3A to 3C.

A liquid crystal display device (display device with a touch sensor function) 10 shown in FIG. 1 includes: a counter substrate (second substrate) 2 and a TFT array substrate (first substrate) 3 provided opposite each other; a liquid crystal panel 1 having a liquid crystal layer (display unit) 4 formed between the counter substrate 2 and the TFT array substrate 3; and a backlight 5 provided below the liquid crystal panel 1.

In addition, the liquid crystal display device 10 has a touch sensor function so that the touch position when performing a touch operation on the upper surface (touch surface 211) of the liquid crystal panel 1 can be detected. The liquid crystal display device 10 is formed as a display device including an input device which controls the display contents, for example, changes the display contents according to the touch position.

Hereinafter, the configuration of each unit of the liquid crystal display device 10 will be described in detail.

The backlight 5 has a function of supplying light to the liquid crystal panel 1, and the configuration is not particularly limited. For example, the backlight 5 includes a laminate body 51, which has a rectangular plate shape and in which a reflecting plate, a light guiding plate, a prism sheet (optical sheet), and a diffusion plate are laminated sequentially from the lower side (opposite side to the liquid crystal panel 1), and a cold cathode fluorescent tube 52 provided on the side surface of the light guiding plate. In addition, an LED or the like may also be used instead of the cold cathode fluorescent tube.

The liquid crystal panel 1 to which light from the backlight 5 is illuminated is provided above the backlight 5. Each of the counter substrate 2 and the TFT array substrate 3 provided in the liquid crystal panel 1 is a colorless and transparent glass substrate which has a rectangular plate shape. The counter substrate 2 and the TFT array substrate 3 are bonded to each other by a sealing member (not shown) which has a rectangular frame shape and is provided along the edge of the counter substrate 2. In addition, the liquid crystal layer 4 is formed by filling a liquid crystal material in a space defined by the counter substrate 2, the TFT array substrate 3, and the sealing member. Using such a liquid crystal layer 4 as a display unit, the liquid crystal display device 10 can show excellent image display function.

An optical substrate 31 formed by a polarizing plate, a retardation film, or the like is bonded to the lower surface (surface facing the backlight 5) of the TFT array substrate 3. The optical substrate 31 has a function of emitting light from the backlight 5 to the liquid crystal layer 4 as linearly polarized light.

On the other hand, as shown in FIG. 2, a plurality of gate lines 81, a plurality of data lines 82, a plurality of pixel electrodes 83, and a plurality of TFTs (thin film transistors) 84 are formed on the upper surface (face facing the liquid crystal layer 4) of the TFT array substrate 3.

The plurality of gate lines 81 is formed with uniform pitches in the longitudinal direction (column direction) in FIG. 2 and extends in the horizontal direction (row direction) in FIG. 2. Each gate line 81 is electrically connected to a gate driver (not shown) provided in the edge of the TFT array substrate 3.

On the other hand, the plurality of data lines 82 is formed with uniform pitches in the horizontal direction (row direction) in FIG. 2 and extends in the longitudinal direction (column direction) in FIG. 2. Each data line 82 is electrically connected to a data driver (not shown) provided in the edge of the TFT array substrate 3.

The pixel electrode 83 and the TFT 84 are provided in each of a plurality of pixel regions (pixels) P surrounded by the pair of adjacent gate lines 81 and the pair of adjacent data lines 82.

An alignment layer 34 having been subjected to orientation processing is formed above each pixel region P with such a configuration, as shown in FIG. 1. The alignment layer 34 is formed of an oriented polymer, such as an oriented polyimide, and sets the orientation of a liquid crystal molecule LC near the corresponding pixel electrode 83 in a predetermined direction.

A polarizing plate 21 which emits linearly polarized light, which is perpendicular to the light from the optical substrate 31, to the outside (upper direction in FIG. 1) is bonded to the upper surface of the counter substrate 2 which is opposite the TFT array substrate 3 with the liquid crystal layer 4 interposed therebetween. The upper surface (surface exposed to the outside of the device) of the polarizing plate 21 forms the touch surface 211 which is touched with an input device, such as a touch pen, an operator's finger, and the like.

On the other hand, a color filter 22 which is formed by a color resist film 221 and a black matrix 222 is provided on the lower surface of the counter substrate 2. In addition, a common electrode 23 is provided below the color filter 22. The common electrode 23 is also formed by a transparent conductive film or the like and has optical transparency, similar to the pixel electrode 83. In addition, an alignment layer 24 having been subjected to orientation processing is formed below the common electrode 23, and sets the orientation of a liquid crystal molecule near the common electrode 23 in a predetermined direction. The common electrode 23 and the pixel electrode 83 form a display electrode.

The gate driver applies a voltage to the plurality of gate lines 81 at a predetermined timing one by one in a sequential manner (for example, sequentially from the gate line 81 located at the upper side in FIG. 2) on the basis of the display contents. As a result, the TFT 84 connected to the gate line 81 to which a voltage has been applied is turned on.

The data driver applies a voltage to each data line 82 according to the timing, at which a voltage is applied to the gate line 81, on the basis of the display contents. The data driver performs such application of a voltage sequentially to all data lines 82 so that the voltage is applied to all pixel electrodes 83.

In each pixel region P, when a voltage is applied to the pixel electrode 83, liquid crystal is driven according to the voltage level. Accordingly, for every pixel region P, when light from the backlight 5 passes through the liquid crystal layer 4, the polarization state of the light can be modulated. As a result, a desired image is displayed on the touch surface 211 by the light having passed through the liquid crystal layer 4.

In addition, a touch electrode 6 having a lower electrode 60, which is provided so as to protrude upward from the TFT array substrate 3, and an upper electrode 65, which is provided below the color filter 22, is provided in the liquid crystal layer 4.

The lower electrode 60 has a spherical core portion 61, a cover layer 62 which covers a surface of the core portion 61, a lower wiring line 64 provided on the TFT array substrate 3, and a fixed portion 63 which is provided between the core portion 61 and the lower wiring line 64 in order to make the core portion 61 and the lower wiring line 64 electrically connected to each other.

The touch electrode 6 is configured so that the lower electrode 60 and the upper electrode 65 come in electrical contact with each other when a touch operation is performed on the touch surface 211. In addition, the touch position on the touch surface 211 can be detected by current application made by the electrical contact.

Here, the core portion 61 has elasticity. Accordingly, the core portion 61 can deform in a flat shape when a pressing force is applied to the core portion 61.

As a material for forming the core portion 61, it is preferable to use an elastic material. For example, various kinds of rubber materials, such as acrylic rubber, nitrile rubber, isoprene rubber, urethane rubber, ethylene propylene rubber, epichlorohydrin rubber, chloroprene rubber, silicon rubber, styrene butadiene rubber, butadiene rubber, fluorine-containing rubber, and butyl rubber, and various kinds of thermoplastic elastomers, such as a styrene based elastomer, an olefin based elastomer, a vinyl chloride based elastomer, a urethane based elastomer, an ester based elastomer, and an amide based elastomer, may be mentioned. Among these materials, a styrene based thermoplastic elastomer is preferably used from a point of view of increasing the elasticity and durability of the core portion 61. In the case of the core portion 61 formed of this material, it is difficult that the elasticity is adversely affected even if the core portion 61 deforms repeatedly by touch operations, and it is possible to maintain the elasticity over a long period of time.

In addition, a filler for giving a conductive property to the core portion 61 may be included in the core portion 61. Metal particles such as copper, copper alloy, silver, nickel, low-melting-point alloy (for example, solder), metal oxide particles such as a zinc oxide, a tin oxide, and an indium oxide, conductive polymer particles such as various kinds of carbon black, polypyrrole, and polyaniline, polymer particles coated with metal, particles of copper or silver coated with precious metal, a metal fiber, and a carbon fiber may be mentioned as examples of the filler.

On the other hand, the cover layer 62 may be a conductive layer. By the cover layer 62, the upper surface of the lower electrode 60 becomes a conductive surface.

An oxide based conductive layer such as a zinc oxide, a tin oxide, an indium oxide, or a compound (mixture) thereof, a metal based conductive layer such as copper, copper alloy, silver, and nickel, a carbon based conductive layer such as graphite, and an organic conductive layer such as polypyrrole, polythiophene, and polyaniline may be mentioned as examples of the cover layer 62.

In addition, when the core portion 61 has a conductive property, it may be omitted to form the cover layer 62. In other words, by forming the cover layer 62, a material which is optimal from a point of view of elasticity can be used as a constituent material of the core portion 61 regardless of conductivity.

In addition, the lower wiring line 64 and the upper electrode 65 may be formed as a film in the same manner as the common electrode 23 or the pixel electrode 83 described above.

In addition, the fixed portion 63 serves to make the core portion 61, on which the cover layer 62 is formed, and the lower wiring line 64 electrically connected and fixed to each other.

For example, paste or dispersion liquid containing a conductive filler described above may be mentioned as the fixed portion 63. For example, it is possible to make the core portion 61 and the lower wiring line 64 electrically connected and fixed to each other by applying dispersion liquid (paste) on the lower wiring line 64, placing on the dispersion liquid the core portion 61 on which the cover layer 62 is formed, and then drying the dispersion liquid.

Next, a method of detecting the touch position on the touch surface 211 using the above touch electrode 6 will be described.

[1] First, in the liquid crystal panel 1 in a state where the touch surface 211 is not touched, the lower electrode 60 and the upper electrode 65 are in a state of being separated from each other, as shown in FIG. 3A. For this reason, a current does not flow between the lower electrode 60 and the upper electrode 65.

In addition, it is preferable that the height of the lower electrode 60 protruding from the TFT array substrate 3 is about 50 to 95% of the thickness of the liquid crystal layer 4 in the state shown in FIG. 3A. More preferably, it is about 60 to 90% of the thickness of the liquid crystal layer 4. As a result, an improvement in detection sensitivity of the touch electrode 6 and a suppression of erroneous detection become highly compatible.

[2] Then, when a touch operation is performed on the touch surface 211, the counter substrate 2 is bent downward. As a result, the upper electrode 65 moves downward with the bending of the counter substrate 2. Then, as shown in FIG. 3B, the lower electrode 60 and the upper electrode 65 come in contact with each other. Accordingly, a current flows through the touch electrode 6.

Such a touch electrode 6 is provided in each of all pixel regions P, and the lower wiring lines 64 of the pixel regions P are electrically connected to each other through resistor circuits (not shown). On the other hand, the upper electrodes 65 are also electrically connected to each other through resistor circuits (not shown).

On the other hand, for example, a current detecting section provided in each of the four corners of the liquid crystal panel 1 is included in the resistor circuit.

When a touch operation is performed on the touch surface 211, a current flows through the resistor circuit connected to the touch electrode 6. However, since the distance between the touch electrode 6 and each current detecting section, that is, the electric resistance changes with the touch position, the current values measured by the current detecting sections are different. Accordingly, it is possible to detect the touch position on the basis of the current value measured by each current detecting section.

In addition, it is also possible to improve the positional accuracy in detection of the touch position by providing the touch electrode 6 in every pixel region P.

Here, the method of detecting a touch position will be described in more detail.

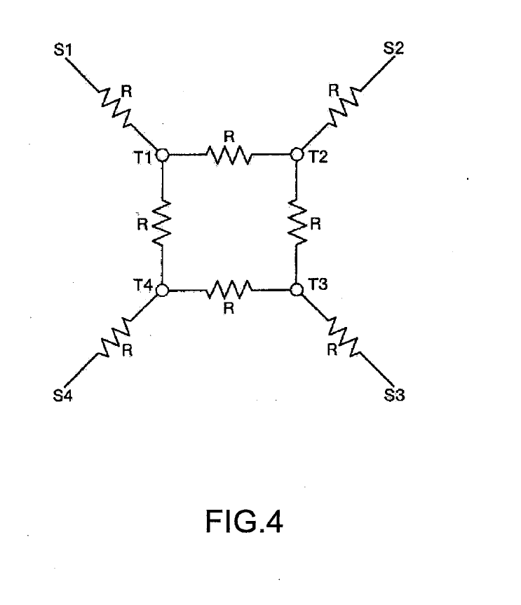

FIG. 4 is a circuit diagram schematically illustrating a touch position detecting method in a touch sensor function.

FIG. 4 shows a model of a liquid crystal panel in which touch electrodes T1 to T4 are provided in 2×2 pixels, and current detecting sections S1 to S4 are provided in the four corners.

In addition, it is assumed that a resistor R is provided between the touch electrodes T1 and T2, between the touch electrodes T2 and T3, between the touch electrodes T3 and T4, and between the touch electrodes T4 and T1. In addition, it is assumed that the resistor R is also provided between the touch electrode T1 and the current detecting section S1, the touch electrode T2 and the current detecting section S2, the touch electrode T3 and the current detecting section S3, and the touch electrode T4 and the current detecting section S4. In addition, although these resistors are originally different, it is assumed that the resistors R are equal herein in a model manner.

In addition, it is assumed that an electrode facing each of the touch electrodes T1 to T4 is electrically grounded and a voltage V is applied between each of the touch electrodes T1 to T4 and the ground electrode.

Here, since one resistor R exists between the touch electrode T2 and the current detecting section S2, the current value detected by the current detecting section S2 becomes V/R if a current flows through the touch electrode T2 by a touch operation.

In addition, since two resistors R exist between the touch electrode T2 and the current detecting section S1, the current value detected by the current detecting section S1 becomes V/(2R).

Similarly, the current value detected by the current detecting section S3 also becomes V/(2R) since two resistors R exist between the touch electrode T2 and the current detecting section S3, and the current value detected by the current detecting section S4 becomes V/(3R) since three resistors R exist between the touch electrode T2 and the current detecting section S4.

That is, in the current detecting sections S1 to S4, the current values which are different according to the electric resistance up to the touch electrode are measured. Accordingly, the coordinates of the touch position can be calculated indirectly. In addition, such a position detecting method is known as a five wire method.

In addition, although the model using 2×2 pixels was described in FIG. 4, the touch position can be detected in the same way even in the case of a larger number of pixels.

[3] Then, a larger pressing force is applied to the touch surface 211. Then, the counter substrate 2 is largely bent downward, and the upper electrode 65 also largely moves downward. As a result, a spherical electrode (hereinafter, simply referred to as a spherical electrode) formed by the core portion 61 and the cover layer 62 deforms in the flat shape as shown in FIG. 3C.

Since the contact area in which the lower electrode 60 and the upper electrode 65 come in contact with each other also changes if the spherical electrode deforms, the contact resistance also changes accordingly. Accordingly, it is possible to detect to what extent the spherical electrodes have deformed by detecting a change in the contact resistance as a change in the current value in each current detecting section described above. In addition, the contact area between the lower electrode 60 and the upper electrode 65 changes with the size of the pressing force applied to the touch surface 211. As a result, a change in the pressing force can be detected on the basis of the change in the current value.

Here, in order to calculate the change in the pressing force on the basis of the change in the current value, the relationship between the contact resistance of the lower electrode 60 and the upper electrode 65 and the amount of downward movement of the upper electrode 65 will be described in detail.

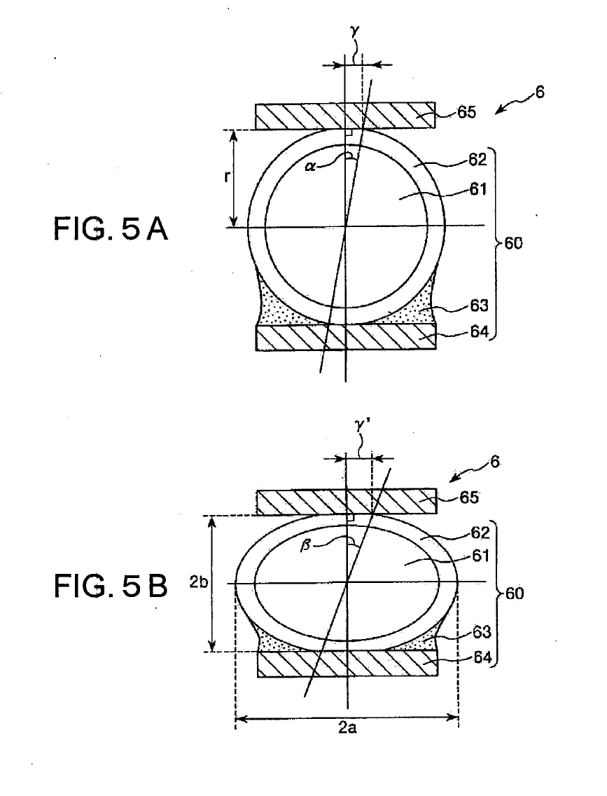

FIGS. 5A and 5B are a partially enlarged view showing the neighborhood of the touch electrode in FIG. 3B and a partially enlarged view showing the neighborhood of the touch electrode in FIG. 3C, respectively.

A spherical electrode shown in FIG. 5A is a state immediately after the lower electrode 60 and the upper electrode 65 come in contact with each other, and this spherical electrode is assumed to be a true sphere with a radius r.

In this case, a contact region between the lower electrode 60 and the upper electrode 65 is circular. In FIG. 5A, the radius of the circle is set to γ and the maximum angle formed by the circumference and the center of the spherical electrode is set to α.

On the other hand, a spherical electrode shown in FIG. 5B is a state when pressing from the upper electrode 65 has been performed with a larger pressing force and as a result, deformation has occurred. Here, it is assumed that the diameter of the spherical electrode in the horizontal direction is set to 2a and the diameter of the spherical electrode in the vertical direction is set to 2b.

In this case, the ellipticity is defined as (a−b)/a. In this case, a contact region between the lower electrode 60 and the upper electrode 65 has a circular shape larger than the area in FIG. 5A. In FIG. 5B, the radius of the circle is set to γ′ and the maximum angle formed by the circumference and the center of the spherical electrode is set to β.

Here, the radius γ of the contact region in FIG. 5A is calculated from the following expression (1).

γ=r tan α (1)

In addition, the radius γ′ of the contact region in FIG. 5B is calculated from the following expression (2).

γ′=b tan β (2)

The contact resistance in each of the contact regions is calculated from the following general expression (3).

R=1/(2γσ) (3)

Here, σ is the conductivity of each of the cover layer 62 and the upper electrode 65. Accordingly, the contact resistance R in FIG. 5A and the contact resistance R′ in FIG. 5B are calculated from the following expressions (4) and (5), respectively.

R=1/(2σr tan α) (4)

R′=1/(2σb tan β) (5)

Here, if α=5, β=15, and b=0.8r are substituted into the expressions (4) and (5) as an example, R=5.715/(rσ) and R′=2.333/(rσ).

As a result, R′ becomes 0.408R. That is, the contact resistance in FIG. 5B which is about 40% of the contact resistance in FIG. 5A is calculated.

In addition, (r-b) corresponding to the amount of downward movement of the upper electrode 65 can be estimated from the amount of change in the contact resistance. Accordingly, in the touch electrode 6, it is possible to detect the touch position on the touch surface 211 and the pressing force (the amount of downward movement of the touch surface) generated by a touch operation together.

In addition, the change in the contact resistance is detected as a change in the current value by the current detecting section provided in each of the four corners of the liquid crystal panel 1, for example. Accordingly, the amount of downward movement of the upper electrode 65 can be estimated on the basis of the above-described calculation method, by taking into consideration the current value when the touch position is detected and the amount of change in the current value when the pressing force has changed by a touch operation thereafter.

Moreover, if the core portion 61 includes conductive fillers, the conductivity of the core portion 61 itself is improved since the conductive fillers are brought closer to each other when the core portion 61 deforms in the flat shape. In this case, since not only the contact resistance is reduced but also the conductivity is improved by the touch operation, the change in the current value described above is detected as a more amplified value. Accordingly, in the case of using the core portion 61 including such a filler, the detection accuracy of the pressing force can be further improved.

According to the liquid crystal panel 1 with such a touch sensor function, when writing a character by tracing the touch surface 211 with a finger or the like, not only the information on the locus traced by the finger but also the information corresponding to so-called writing pressure can be acquired. Accordingly, by adding the information on the writing pressure to the information on the locus, it is possible to generate the input data in which individually different handwriting is sufficiently reproduced.

In addition, the information on a touch operation can be reflected in the display contents of the liquid crystal panel 1 by inputting the information on the touch operation to the data driver and the gate driver or to a operational circuit (CPU) which controls operations of the drivers according to the contents displayed.

Next, a manufacturing method of such a liquid crystal panel 1 will be described.

First, the TFT array substrate 3 is prepared and the gate lines 81, the data lines 82, the pixel electrodes 83, the TFTs 84, the lower wiring lines 64, and the like are formed on the upper surface of the TFT array substrate 3.

Then, the core portion 61 covered with the cover layer 62 is disposed in each of the plurality of pixel regions P surrounded by the pair of adjacent data lines 82 and the pair of adjacent gate lines 81.

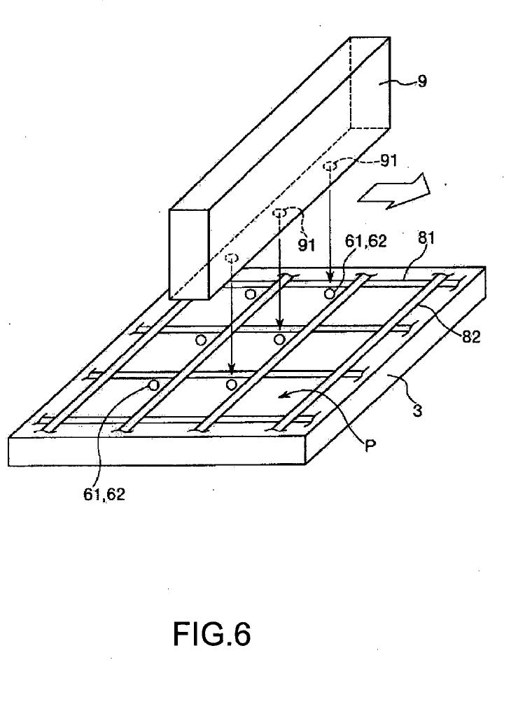

Although this arrangement method is not particularly limited, a method using an ink jet head 9 as shown in FIG. 6 will be described in the present embodiment.

The ink jet head 9 shown in FIG. 6 has a nozzle (ink nozzle) 91 through which the core portion 61 covered with the cover layer 62 (hereinafter, simply referred to as the “core portion 61”) can be ejected. From the nozzle 91, the plurality of core portions 61 stored in the cavity (not shown) inside the ink jet head 9 can be ejected one by one or in a plural number. Accordingly, the core portions 61 can be arrayed efficiently.

In addition, the plurality of nozzles 91 is provided in the ink jet head 9 and provided in a line with equal distances therebetween. In addition, the distance between the adjacent nozzles 91 is the same as the pitch between the pixel regions P. According to the ink jet head 9 which has such a nozzle 91, the core portions 61 can be arrayed in each pixel region P simply and accurately. Particularly when the core portion 61 has an approximately spherical shape, there is no anisotropy of shape and it is difficult to be caught in the nozzle 91 or the like, it is possible to dispose the core portions 61 with higher precision.

In addition, compared with a case where the touch electrode 6 is manufactured by combination of a film forming method, a photolithography method, and an etching method, the cost can be greatly reduced and the manufacturing process can be reduced.

In addition, when the core portion 61 is ejected from the ink jet head 9, it is preferable that the core portion 61 is ejected in a state of dispersion liquid. In this case, any thing may be used as a dispersion medium as long as it does not cause change of properties, deterioration, and the like in the core portion 61 or the pixel region P.

Moreover, in a region where the core portion 61 of each pixel region P is disposed, a liquid coat for forming the fixed portion 63 beforehand may be formed, or the core portion 61 may be ejected from the nozzle 91 together with a liquid material for forming the fixed portion 63. In this case, the core portion 61 lands in each pixel region P in a state where the surface is coated with the liquid material.

Then, the fixed portion 63 is formed by drying the liquid coat or the liquid material.

In this case, the fixed portion 63 which covers the core portion 61 may be made to have a function of the cover layer 62. Accordingly, even when the core portion 61 is formed of an insulating material, the cover layer 62 may also be omitted.

In addition, any pattern may be adopted as an arrangement pattern of the nozzles 91 without being limited to that shown in FIG. 6.

In addition, the distance between the adjacent nozzles 91 may be ½ or integral multiple of the pitch between the pixel regions P. In addition, it is not necessary to eject the core portions 61 from all nozzles 91, and the core portions 61 may be ejected from some nozzles 91.

Subsequently, the counter substrate 2 is prepared and the common electrode 23, the upper electrode 65, the color filter 22, and the like are formed.

Then, the TFT array substrate 3 and the counter substrate 2 are disposed opposite each other, and the edges thereof are sealed by resin. Then, liquid crystal is injected between the TFT array substrate 3 and the counter substrate 2.

In this manner, the liquid crystal display device 10 is obtained.

According to the liquid crystal display device 10 configured as described above, it is not necessary to provide an additional touch panel device at the upper side (display surface side) of the device because a touch sensor function is included in the device. Therefore, since the number of layers through which transmitted light passes can be reduced in the liquid crystal display device 10, not only a satisfactory image can be supplied but also it is possible to make the device small and thin.

Moreover, by the touch sensor function of the liquid crystal display device 10, it is possible to detect not only the touch position at the time of a touch operation but also the pressing force in the touch operation. For this reason, different information other than the touch position can be input according to the size of the pressing force. That is, the touch sensor function serves as an input device which helps to input more complicated information, and the liquid crystal display device 10 can output the display of different contents according to the size of the pressing force.

### Second Embodiment

Next, a display device with a touch sensor function according to a second embodiment of the invention will be described.

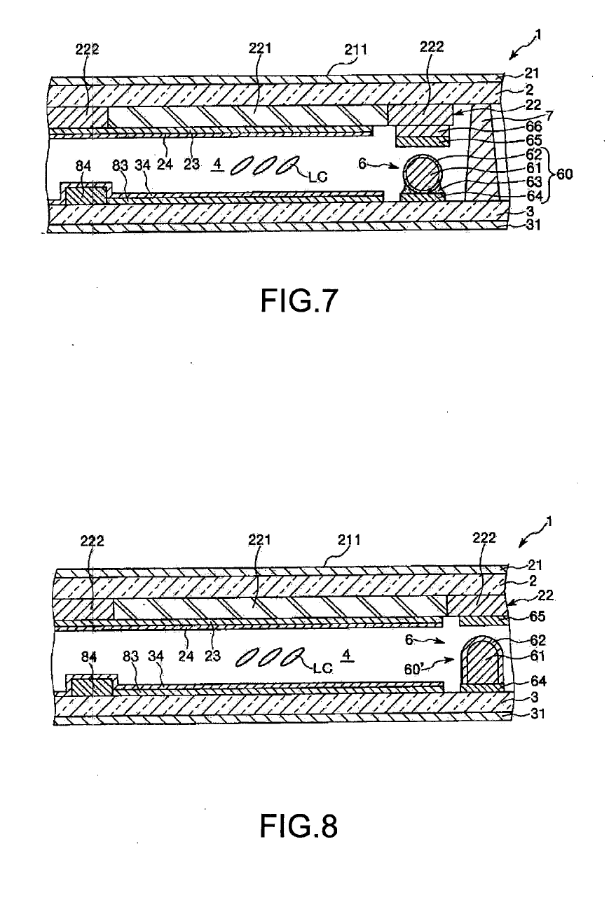

FIG. 7 is a cross-sectional view showing the display device with a touch sensor function according to the second embodiment of the invention. In addition, in the following explanation, it is assumed that the upper side in FIG. 7 is “upper” and the lower side is “lower”. In addition, one of a number of pixels provided in the display device with a touch sensor function is representatively shown in FIG. 7.

Hereinafter, the display device with a touch sensor function according to the second embodiment of the invention will be described with reference to FIG. 7. Moreover, the explanation will be focused on different points from the above-described embodiment, and the same things will not be repeated.

The present embodiment is the same as the first embodiment except that the configuration of the upper electrode 65 is different and a spacer 7 is provided in the liquid crystal layer 4.

A base 66 is provided between the upper electrode 65 shown in FIG. 7 and the color filter 22. By providing the base 66, the position of the upper electrode 65 shifts downward. Accordingly, the diameter of the core portion 61 can be reduced without changing the thickness of the liquid crystal layer 4. In other words, by adjusting the thickness of the base 66, the distance between the lower electrode 60 and the upper electrode 65 can be appropriately adjusted without changing the thickness of the liquid crystal layer 4 or the diameter of the core portion 61.

In addition, the detection sensitivity of the touch sensor function in the liquid crystal display device 10 can be improved by adjusting the thickness of the base 66 so that the distance between the lower electrode 60 and the upper electrode 65 can be made as small as possible.

In addition, the spacers 7 are provided, in every pixel region P or in a predetermined intermittent arrangement pattern, adjacent to the touch electrode 6 and between the counter substrate 2 and the TFT array substrate 3. By providing the spacer 7, the distance between the counter substrate 2 and the TFT array substrate 3 can be accurately controlled.

In addition, the spacer 7 is formed of materials (for example, a silicon oxide, various kinds of ceramic materials, or various kinds of resin materials) which are deficient in elasticity and which have relatively high rigidity. Accordingly, even when the counter substrate 2 bends downward by a touch operation performed on the touch surface 211, the amount of bending can be adjusted by the spacer 7.

In addition, when the pressing force is removed after performing a touch operation on the liquid crystal display device 10, it is preferable that the counter substrate 2 returns to the state before the touch operation. However, if the touch operation is repeated over a long period of time, the mechanical property of the counter substrate 2 deteriorates gradually. As a result, even if the pressing force generated by the touch operation is removed, the counter substrate 2 may not return to the original state.

On the other hand, in the liquid crystal display device 10 shown in FIG. 7, such a problem is suppressed because the spacer 7 regulates the distance between the counter substrate 2 and the TFT array substrate 3. As a result, the liquid crystal display device 10 according to the present embodiment can show a touch sensor function which is excellent over a long period of time.

### Third Embodiment

Next, a display device with a touch sensor function according to a third embodiment of the invention will be described.

FIG. 8 is a cross-sectional view showing the display device with a touch sensor function according to the third embodiment of the invention. In addition, in the following explanation, it is assumed that the upper side in FIG. 8 is “upper” and the lower side is “lower”. In addition, one of a number of pixels provided in the display device with a touch sensor function is representatively shown in FIG. 8.

Hereinafter, the display device with a touch sensor function according to the third embodiment of the invention will be described with reference to FIG. 8. Moreover, the explanation will be focused on different points from the above-described embodiments, and the same things will not be repeated.

The present embodiment is the same as the first embodiment except that the configuration of the lower electrode 60 is different.

In a lower electrode 60′ shown in FIG. 8, the core portion 61 is formed by a columnar member whose upper end has a convex curved surface. In addition, the cover layer 62 is provided to cover the core portion 61, and the fixed portion 63 is not provided. The core portion 61 with such a shape is more reliably fixed to the TFT array substrate 3.

The curved surface of the upper end of the core portion 61 may be formed in any shape as long as it is a curved shape which is convex upward. Preferably, the curved surface of the upper end of the core portion 61 has a spherical or parabolic shape.

Also in the present embodiment, the same operations and effects as in the first embodiment are acquired.

### Electronic Apparatus

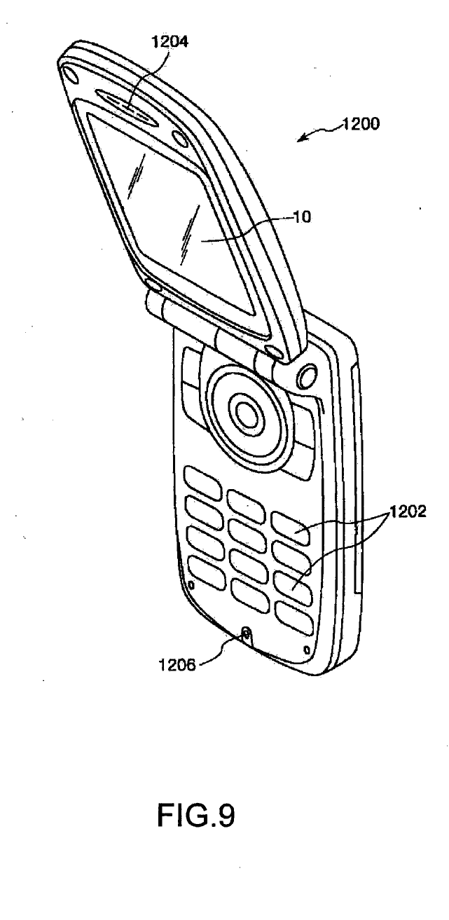

Next, an electronic apparatus according to another embodiment of the invention which includes the liquid crystal display device 10 described above will be described with reference to FIG. 9.

FIG. 9 is a perspective view showing the configuration of a mobile phone (PHS is also included) to which the electronic apparatus according to the embodiment of the invention has been applied.

In FIG. 9, a mobile phone 1200 includes a plurality of operation buttons 1202, an earpiece 1204, a mouthpiece 1206, the liquid crystal display device 10 described above, and a backlight (not shown).

Moreover, examples of the electronic apparatus according to the embodiment of the invention include not only the mobile phone shown in FIG. 9 but also a personal computer (mobile personal computer), a digital still camera, a projection type display device, a television, a video camera, a view finder type or monitor direct view type video tape recorder, a car navigation system, a pager, an electronic diary (electronic diary with a communication function is also included), an electronic dictionary, an electronic calculator, an electronic game machine, a word processor, a workstation, a video phone, a television monitor for security, electronic binoculars, a POS terminal, an apparatus having a touch panel (for example, a cash dispenser in a financial institution or an automatic ticket vending machine), medical equipment (for example, an electronic thermometer, a sphygmomanometer, a blood sugar meter, an electrocardiographic display device, ultrasonic diagnostic equipment, a display device for endoscope), a fish detector, various kinds of measuring equipment, instruments (for example, instruments for vehicles, aircraft, and ships), and a flight simulator. Moreover, it is needless to say that the above-described touch panel device according to the embodiment of the invention may be applied as display units or monitor units of the various electronic apparatuses.

While the display device with a touch sensor function, the manufacturing method of the display device with a touch sensor function, and the electronic apparatus of the invention have been described on the basis of the embodiments shown in the drawings, the invention is not limited thereto.

For example, in the display device with a touch sensor function and the electronic apparatus of the invention, the configuration of each section may be replaced by an arbitrary configuration with the same function, and an arbitrary configuration may be added.

Moreover, in the manufacturing method of the display device with a touch sensor function of the invention, an arbitrary process may be added.

In addition, although the display device with a touch sensor function was described using a liquid crystal display device as an example in each of the embodiments, the display device with a touch sensor function of the invention may also be applied to display devices other than the liquid crystal display device, for example, an electrophoresis display device or a magnetic electrophoreis display device.

In addition, if necessary, the pixel electrode 83 may also be used as the lower wiring line 64. That is, the pixel electrode 83 may also serve as the lower wiring line 64. In this case, a display image near the touch position may be slightly disordered by a touch operation. However, taking into consideration that the counter substrate 2 bends by the touch operation, it is thought that such image disorder will not have an influence on image recognition.

In addition, if necessary, the common electrode 23 may also be used as the upper electrode 65. That is, the common electrode 23 may also serve as the upper electrode 65. Also in this case, a display image may be slightly disordered by a touch operation, but it is thought that such image disorder will be mostly allowable in the image recognition similar to those described above.

Moreover, in each of the embodiments described above, the upper electrode 65 has a flat plate shape. However, the upper electrode 65 may have a shape with a curved surface which is convex downward, and the lower electrode 60 may have a flat plate shape.

In addition, the two or more lower electrodes 60 and the two or more upper electrodes 65 may be provided in each pixel region P.

### EXAMPLES

Next, a specific example of the invention will be described.

First, a TFT array substrate in which gate lines, data lines, pixel electrodes, TFTs, lower wiring lines, and the like were formed was prepared.

Then, dispersion liquid containing beads of a styrene based thermoplastic elastomer was supplied into the cavity of an ink jet head, and the beads were arrayed on the TFT substrate in the same way as in ink jet printing. Then, the discharged dispersion liquid was dried to fix the beads.

The pitch between the arrayed beads was measured. As a result, the pitch was almost the same (150 μm) as the pitch between ink nozzles of the ink jet head.

On the other hand, a counter substrate in which a common electrode, upper electrodes, color filters, and the like were formed was prepared.

Then, the TFT array substrate and the counter substrate were disposed opposite each other, and the edges thereof were sealed by resin. Then, liquid crystal was injected between the TFT array substrate and the counter substrate, and the inlet was sealed.

In this way, a liquid crystal display device was manufactured.

In addition, the liquid crystal display device was set beforehand such that a touch position was displayed as a point according to a touch operation on a touch surface and the locus of movement was displayed as a line when the touch position moved.

In addition, the liquid crystal display device was set beforehand such that the size of a point was displayed to be large or the thickness of a line was displayed to be large when the pressing force in the touch operation was increased.

Moreover, when the touch surface of the obtained display device with a touch sensor function was traced with a finger, it was possible to draw the line along the traced locus. In addition, when the touch surface was traced strongly, the thicker line could be drawn.

The entire disclosure of Japanese Patent Application No. 2009-062098, filed Mar. 13, 2009 is expressly incorporated by reference herein.

What is claimed is:

1. A display device with a touch sensor function comprising:
a first substrate;
a second substrate which is disposed opposite the first substrate and has a touch surface at an opposite side of the first substrate;
a display unit provided between the first and second substrates;
display electrodes which are provided on both a surface of the first substrate facing the display unit and a surface of the second substrate facing the display unit and which control display of the display unit; and
touch electrodes for detecting the touch position on the touch surface which are provided on both the surface of the first substrate facing the display unit and the surface of the second substrate facing the display unit and which come in contact with each other by a touch operation on the touch surface, the touch electrodes provided on at least one of both the surfaces being provided to protrude toward the display unit side,
wherein each of the touch electrodes provided on the one surface has a contact surface, which is a curved surface with a convex shape, and is formed of an elastic material.

2. The display device with a touch sensor function according to claim 1,
wherein each of the touch electrodes provided on the one surface is formed as an approximately spherical body.

3. The display device with a touch sensor function according to claim 1,
wherein each of the touch electrodes provided on the one surface is formed as a columnar body with a curved convex portion on a front end.

4. The display device with a touch sensor function according to claim 1,
wherein each of the touch electrodes provided on the one surface has a core portion, which is formed of an elastic material, and a conductive layer which covers the core portion.

5. The display device with a touch sensor function according to claim 1,
wherein the elastic material is a styrene based thermoplastic elastomer.

6. The display device with a touch sensor function according to claim 1,
wherein the elastic material is an elastic resin material containing conductive fillers therein.

7. The display device with a touch sensor function according to claim 1,
wherein a protrusion height of each of the touch electrodes provided on the one surface is 50 to 95% of the thickness of the display unit in a state where no touch operation has been performed on the touch surface.

8. The display device with a touch sensor function according to claim 1,
wherein a touch position on the touch surface and the strength of a touch operation are detected according to the contact area between the touch electrodes provided on the one surface and the other electrodes provided on the other surface.

9. The display device with a touch sensor function according to claim 1,
wherein the touch electrodes are provided corresponding to pixels of the display unit.

10. The display device with a touch sensor function according to claim 1, further comprising:
spacers which are provided for every pixel of the display unit so as to be adjacent to the touch electrodes and which regulate a distance between the first and second substrates.

11. The display device with a touch sensor function according to claim 1,
wherein the display unit is a liquid crystal layer.

12. A manufacturing method of a display device with a touch sensor function including a first substrate, a second substrate which is disposed opposite the first substrate and has a touch surface at an opposite side of the first substrate, a display unit provided between the first and second substrates, display electrodes which are provided on both a surface of the first substrate facing the display unit and a surface of the second substrate facing the display unit and which control display of the display unit, and touch electrodes for detecting the touch position on the touch surface which are provided on both the surface of the first substrate facing the display unit and the surface of the second substrate facing the display unit, the touch electrodes provided on at least one of both the surfaces being provided to protrude toward the display unit side, the method comprising:
disposing the touch electrodes provided on the one surface by ejecting from ink nozzles for an ink jet head.

13. The manufacturing method of a display device with a touch sensor function according to claim 12,
wherein the touch electrodes provided on the one surface are provided corresponding to pixels of the display unit, and
a nozzle pitch between the ink nozzles for the ink jet head is equivalent to a pixel pitch of the display unit.

14. An electronic apparatus comprising the display device with a touch sensor function according to claim 1.
